(19) United States
(12) Patent Application Publication
(10) Pub. No.: US 2025/0027985 A1
(43) Pub. Date: Jan. 23, 2025

(54) STRESS CALIBRATION METHOD, CORRESPONDING ELECTRONIC DEVICE

(71) Applicant: STMicroelectronics International N.V., Geneva (CH)

(72) Inventors: Emanuele Moretti, Milano (IT); Mauro Foppiani, Milano (IT)

(21) Appl. No.: 18/752,038

(22) Filed: Jun. 24, 2024

(30) Foreign Application Priority Data
Jul. 18, 2023 (IT) 102023000015036

(51) Int. Cl. G01R 31/27; G01R 31/00; G01R 31/26; G01R 31/30; G01R 31/52

(52) U.S. Cl. CPC G01R 31/275; G01R 31/006; G01R 31/2621; G01R 31/3008; G01R 31/52

(57) ABSTRACT

A test circuit includes a set of electronic switches having a current path between a first node and a ground node, where each electronic switch has a respective control node. A set of coupling channels have one end coupled to a common test node and other ends coupled to the respective control nodes of electronic switches. A stress voltage supply source is coupled to the common test node. A set of comparator circuits includes comparator circuits having a first input node coupled, via sensing circuitry, to the control node of respective electronic switches in the set of electronic switches and having second nodes coupled to a threshold voltage node. A method of operating the test circuit is also disclosed.

### CROSS-REFERENCE TO RELATED APPLICATIONS

This application claims the benefit of Italian Patent Application No. 102023000015036, filed on Jul. 18, 2023, which application is hereby incorporated herein by reference.

### TECHNICAL FIELD

The description relates to a stress calibration method and a corresponding electronic device.

### BACKGROUND

An ECU or engine control module (briefly, ECM) is an electronic control unit configured to process signals from sensors and configured to control a series of actuators equipped on an (e.g., internal combustion or electric) engine based on signals received from sensors equipped on the engine. An ECU may comprise electric loads, such as sensors, LEDs, and other loads such as resistive and/or inductive load circuits.

Power transistors employed in half-bridge arrangements may be subject to reliability tests during their manufacturing. For instance, a pulsed-gate stress test (briefly, gate stress) approach comprises a method to identify defects that, if the test is not performed and/or is not effective, may emerge during IC usage, even after some time. For instance, the gate stress method is performed at wafer level for quality checks. The application of the gate stress may comprise a test circuit that uses dedicated pads coupled to internal gates of the power MOSFETs under test.

The gate stress test comprises, for instance, measuring a first gate leakage current before applying a voltage stress to the transistor. During a test time interval (e.g., hundreds of milliseconds, 1 millisecond=1 ms=10⁻³ s), a stress voltage equal or higher absolute maximum rating (AMR parameters) that is a maximum voltage that an electronic component can sustain without damage among its (e.g., gate-source) terminals is applied. At lapse of the test time interval, a second gate leakage current is measure and a comparison of the first and the second gate leakage currents is performed.

In case the comparison yields that the second current is greater than the first, this may indicate the presence of a latent gate oxide defect in the transistor, not visible during normal operation at room temperature, activated in response to the stress voltage application, for instance. Therefore, the transistor under test may be labeled as faulty.

Devices comprising integrated power MOSFETs can further comprise gate-source voltage comparators configured to produce a first (e.g., “high” or “1”) state in response to the voltage across gate and source terminals of the power transistor is above the threshold during the turn on phase. The output of this comparator can be used for different purposes in functional mode (such as overload diagnosis structures, management of dead times, etc.)

During the gate stress procedure, the current sunk by low side driver circuitry (in particular in multiple-channels devices) can be appreciable (e.g., in the range of 10 milliAmpere, with 1 milliAmpere=1 mA=10⁻³ A).

This may lead to an equally appreciable voltage drop on internal metal connections, for instance between the pad used to force the stress voltage with EWS probe (tests at wafer level) and the effective gate-to-source voltage applied during stress.

Such a scenario can be difficult to detect and it may lead to a lack of effective stress on all or some drivers. Also at the simulation level, it can be hard to understand the phenomenon without considering metal connections and parasitic components.

Any discrepancy between simulation results and automatic test equipment (ATE) level measurements can indicate an appreciable risk of the presence of underperforming parts during pre-production steps (e.g., due to failures such as “burn in” test or field returns).

### SUMMARY

The description relates to methods and systems for testing circuits, such as low side driver circuits comprising metal-oxide-semiconductor field-effect (briefly, MOS-FET) transistors, for instance.

One or more embodiments may be applied in integrated circuits (ICs) comprising power MOSFETs, such as an engine control unit (ECU) of an automotive engine management system (EMS), for instance.

One or more embodiments can contribute in mitigating the issues mentioned above. For instance, the proposed solution can introduce a better control of the stress voltage applied during a gate stress procedure.

One or more embodiments may relate to a corresponding test circuit.

One or more embodiments may relate to a corresponding vehicle.

One or more embodiments comprise comparing the stress voltage applied during testing with an internal threshold.

One or more embodiments may lead to an improved control of the gate stress procedure.

One or more embodiments counter the risk of having power MOSFET gates poorly stressed during the test phase.

One or more embodiments facilitate reducing the probability to have burn-in failures and/or field returns related to gate oxide defectiveness.

One or more embodiments facilitate to have quick feedback from a test device indicative of the effective gate voltage applied to individual power (e.g., MOSFET) transistors under test.

### BRIEF DESCRIPTION OF THE DRAWINGS

One or more embodiments will now be described, by way of non-limiting example only, with reference to the annexed figures, wherein:

FIG. 1 is a diagram exemplary of a circuit as per the present disclosure,

FIG. 2 is a diagram exemplary of a circuit as per the present disclosure,

FIG. 3 is a diagram exemplary of a test device as per the present disclosure,

FIG. 4 is a diagram exemplary of a vehicle as per the present disclosure.

Corresponding numerals and symbols in the different figures generally refer to corresponding parts unless otherwise indicated.

The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The references used herein are provided merely for convenience and hence do not define the extent of protection or the scope of the embodiments.

For the sake of simplicity, in the following detailed description a same reference symbol may be used to designate both a node/line in a circuit and a signal which may occur at that node or line.

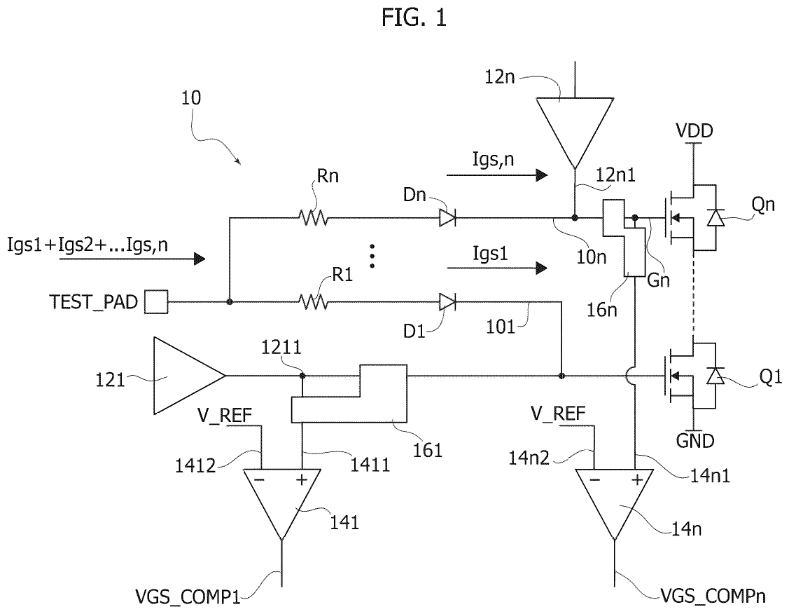

As exemplified in FIG. 1, a circuit 10 for performing a stress test at a control terminal GQ (e.g., gate terminal) of a (e.g., MOSFET) transistor Q comprises a test input node TEST_PAD configured to be coupled to an electrical source configured to generate a stress voltage to perform a test of the circuit 10. For example, a total current equal to a sum Igs1+Igs2+ . . . +Igsn can be provided. Electrical currents Igs1, . . . , Igsn flowing in a set of test channels 101, . . . , 10n for electronic switches Q1, . . . , Qn are discussed in the following.

A set of electronic switches Q1, . . . , Qn have respective control nodes G1, . . . , Gn configured to be coupled to the test input node TEST_PAD to be put under test. A set of test channels 101, . . . , 10n couple the test input node TEST_PAD to the control nodes G1, . . . , Gn of respective electronic switches in the set of electronic switches Q1, . . . , Qn. For instance, each test channel in the set of test channels 101, . . . , 10n may comprise a series arrangement of a resistive element and a diode belonging to respective sets of resistive elements R1, . . . , Rn and diodes D1, . . . , Dn.

A set of driver circuits 121, . . . , 12n are provided. Each driver circuit in the set of driver circuits 121, . . . , 12n is configured to provide, at a respective driver output node of a set of driver output nodes 1211, . . . , 121n, a respective control signal to the respective control terminal G1, . . . , Gn of the respective electronic switch in the set of electronic switches Q1, . . . , Qn.

A set of (e.g., voltage) comparator circuits 141, . . . , 14n is coupled to a reference node V_REF to receive a reference (e.g., voltage) value V_REF therefrom and is coupled to the set of electronic switches Q1, . . . , Qn. Each comparator circuit in the set of comparator circuits 141, . . . , 14n comprises a respective first input node 1411, . . . , 14n1 coupled to the respective output node 1211, . . . , 12n1 of the respective driver circuit in the set of driver circuits 121, . . . , 12n and a second input node 1412, . . . , 14n2 coupled to the reference node V_REF.

A set of coupling circuit blocks 161, . . . , 16n is interposed the first input nodes 1411, . . . , 14n1 of the comparator circuits in the set of comparator circuits 141, . . . , 14n, and the control nodes G1, . . . , Gn of the electronic switches in the set of electronic switches Q1, . . . , Qn. The coupling circuit blocks in the set of coupling circuit blocks 161, . . . , 16n comprise circuitry configured to selectively couple the control nodes G1, . . . , Gn of electronic switches in the set of electronic switches Q1, . . . , Qn to the comparator circuits in the set of comparator circuits 141, . . . , 14n.

For instance, each comparator circuit in the set of comparator circuits 141, . . . , 14n is configured to be coupled, via the coupling circuit blocks in the set of coupling circuit blocks 161, . . . , 16n, to each respective control node of the electronic switches perform a comparison among the reference value V_REF and (e.g., voltage) signals sensed at the control nodes of the respective devices under test Q1, . . . , Qn. The comparator circuits 141, . . . , 14n are further configured to produce respective comparison signals VGS_COMP1, . . . , VGS_COMPn as a result.

As exemplified in FIG. 1, the reference value V_REF is greater than a minimum stress voltage (e.g., V_REF>V_STRESS_MIN) that the circuit 10 is designed to deliver to the devices under test in the set of electronic switches Q1, . . . , Qn.

As exemplified herein, each comparator in the set of comparators is configured to detect, in response to the stress test voltage V_STRESS_MIN being applied at the test input node TEST_PAD, whether the actual signal sensed at the respective control node (e.g., G1) of the respective device under test (e.g., Q1) in the set of electronic switches Q1, . . . , Qn exceeds or fails to exceed (in other words, reaches or fails to reach) the reference voltage value V_REF.

For instance, in case the comparison yields that the sensed signal fails to exceed the reference value V_REF, the application of the stress test voltage V_TEST_MIN is repeated for the i-th switch (e.g., first switch Q) in the set of electronic switches Q1, . . . , Qn.

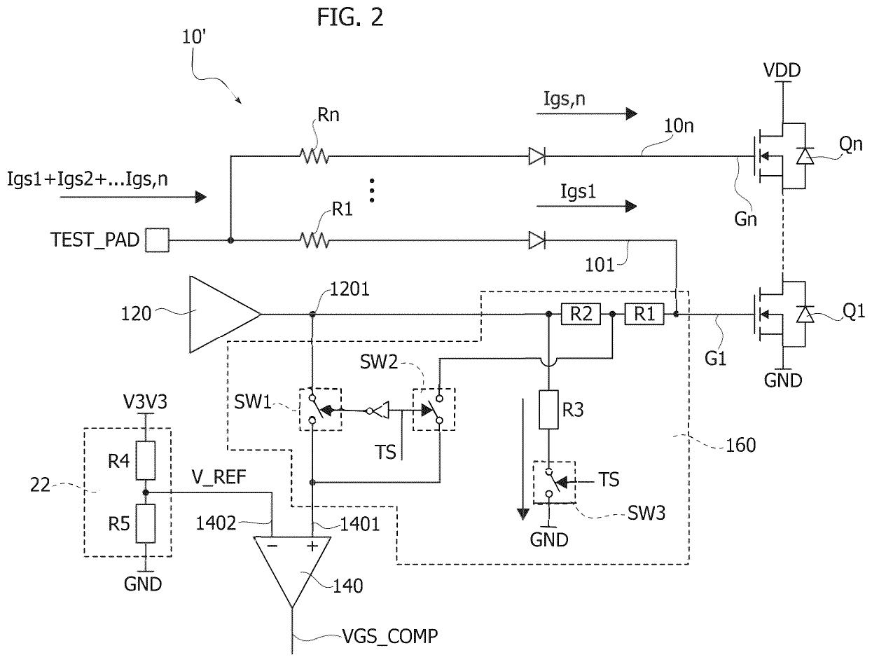

FIG. 2 shows an alternative circuit 10′ where a single comparator 140 is used for an electronic switch (e.g., the first electronic switch Q1) in the set of electronic switches Q1, . . . , Qn. Such an example is purely exemplary and in no way limiting, being otherwise understood that the implementation shown in FIG. 2 may be combined with that of FIG. 1 with the blocks shown in FIG. 2 for a channel being repeated for a subset or for all channels of electronic switches under test.

The circuit 10′ is configured to facilitate applying stress voltage at the control terminal GQ of at least one transistor(s) Q1 under test. A driver circuit 120 is configured to provide, at a respective driver output node 1201, a respective control signal to the respective control terminal G1 of the first electronic switch Q1. A comparator circuit 140 comprises a first input node 1401 coupled to the output node 1201 of the driver circuit 120 and a second input node 1402 coupled to the reference node V_REF. The comparator circuit 140 is configured to produce a comparison signal VGS_COMP based on the comparison of signals received at input nodes 1401, 1402.

A coupling circuit 160 is interposed the first input node 1401 of the comparator circuit 140 and the control node G1 of the first electronic switch Q1. The coupling circuit 160 comprising circuitry is configured to selectively couple the control node G1 of first electronic switch Q1 to the comparator circuit 140.

A supply voltage node V3V3 configured to provide a supply voltage level, e.g., 2.7 Volt. A voltage threshold generator circuit block 22 comprises a (e.g., resistive) voltage divider R4, R5 interposed between the supply voltage V3V3 and ground GND. The voltage threshold source 22 is coupled to the second input node 1402 of the voltage comparator 140 to provide the voltage threshold level V_REF thereto.

As shown in the example of FIG. 2, the coupling circuit block 160 comprises a first switch SW1 interposed between the output node 1201 of the driver circuit 120 and the first input node 1401 of the voltage comparator 140 and a second switch SW2 interposed between the first input node 1401 of the comparator 140 and a set of resistive elements R1, R2, which comprises a first resistive element R1 in series with a second resistive element R2. The set of resistive elements R1, R2 is arranged between the control node G1 of the first electronic switch Q1 and the output node 1201 of the driver circuit 120.

A third switch SW3 is interposed between a third resistive element R3 having one end coupled to the set of resistive elements R1, R2, (specifically, intermediate the first and second resistive elements) and ground GND. An inverter circuit 1601 is coupled to the first switch SW1 and configured to receive a calibration enable signal TS to operate the switch SW1.

As shown in FIG. 2, the first SW1, second SW2 and third SW3 switches are each configured to switch between a first (“closed” or “ON”) state in which they are made conductive and a second (“open” or “OFF”) state in which they are made non-conductive based on the calibration enable signal TS. Specifically, among the first SW1 and the second switch SW2, only one may be made conductive at the same time thanks to the presence of the inverter circuit 1601.

In one or more embodiments, using a fraction of the supply voltage V3V3 as a reference voltage facilitates calibrating the procedure to define the minimum stress voltage level.

In one embodiment, a method of calibrating a gate stress procedure comprises asserting the calibration enable signal TS with a first logic value (e.g., “1” or “true”), thereby switching the first switch SW1 in the second OFF state while switching the second SW2 and third SW3 switches in the first ON state. A calibration voltage level (e.g., multiple of a step about 100 mV) is applied to the test pad node coupled to the first test channel 101 coupled to the first electronic switch Q1.

After application of the stress test voltage, a control voltage sensed at the control node G1 of the first electronic switch Q1 is received at the first input node 1401 of the comparator 140, via the resistive divider formed by resistive elements R1, R2, R3.

A threshold reference voltage V_REF is provided at the second input node 1402 of the comparator circuit 140. A comparison of the sensed control voltage and the threshold reference voltage V_REF is performed, producing a comparison signal VGS_COMP as a result having a first logic value (e.g., “1” or “high”) in response to the sensed control voltage exceeding the threshold reference voltage V_REF and a second logic value (e.g., “0” or “low”) otherwise.

In response to the comparison signal VGS_COMP having the second logic value, the calibration voltage level (e.g., by a step about 100 mV) is increased and the operations of the method discussed in the foregoing are repeated until the comparison signal VGS_COMP has reached the first logic value. This operation provides an indication of an effective stress voltage level V_STRESS_MIN equal to the calibration voltage that produces the first logic value of the comparison signal VGS_COMP, for instance, providing it to user circuitry such as an engineering work station (EWS).

At the end of the calibration procedure, that is, after obtaining the value of the effective stress voltage level V_STRESS_MIN, the calibration enable signal TS is asserted to the second logic level (e.g., “0” or “low”) in order to couple the first input node 1401 of the comparator circuit 140 to the output node 1201 of the driver circuit 12.

As shown in FIG. 2, the resistive elements R1, R2, R3 of the coupling circuitry 160 and the resistive elements R4, R5 in the threshold voltage generator circuit block 22 may have resistance values linked by some relation therebetween. For instance, the first R1 and second resistive elements R2 may have a resistance value equal to the resistance value of a fourth resistive element R4 in the threshold voltage generator circuit block 22. The third resistive element R3 may have a resistance value equal to the resistance value of a fifth resistive element R5 in series with the fourth resistive element in the threshold voltage generator circuit block 22.

As discussed herein, the resistive elements R1, R2, R3 of the coupling circuitry 160 are designed so as to protect the CMOS driver from excessive stress voltages during the test phase. For instance, a maximum voltage applicable to the driver may be about 3.6 volts for a 4.6 volts of AMR while during the gate stress procedure the voltages may reach values about 6 volts.

Due to the use of the coupling circuit 160, it is possible to exploit a reference voltage VREF which is a fraction of the internal supply voltage V3V3 (e.g., 3.3 volts), in order to counter the risk of having to use higher values (e.g., 6 volts).

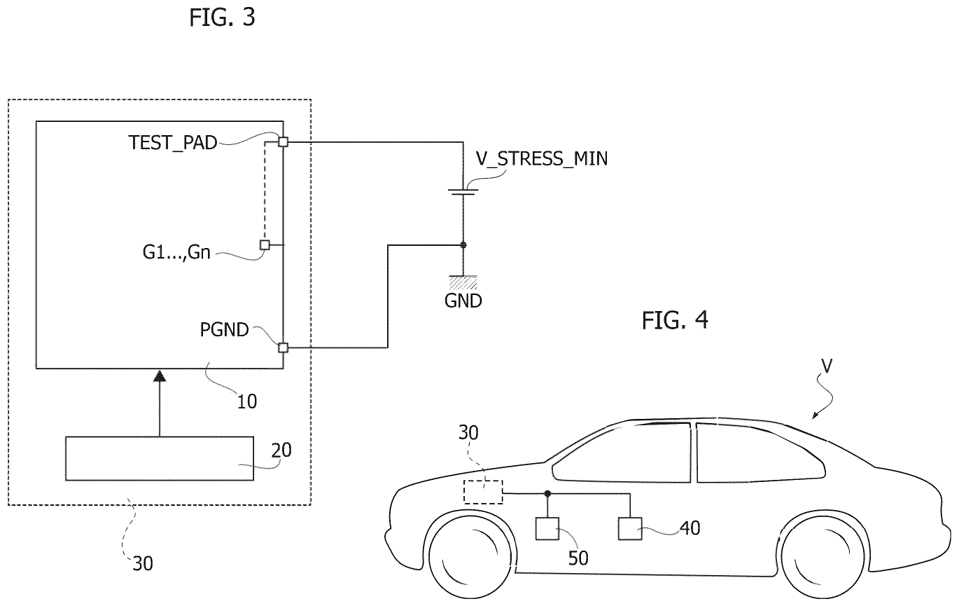

As shown in the example of FIG. 3, an electronic device 30 (e.g., to be used in a test production phase) comprises an internal power supply source 20 configured to be coupled to a voltage generator to apply the stress voltage V_STRESS_MIN (obtained as a result of the calibration procedure) thereto via the TEST_PAD node of the circuit 10, 10′ to verify its state.

FIG. 4 provides an example of one or more embodiments of a (e.g., wheeled and/or electrically powered) vehicle V comprising a set of electronic control units 40, 50 coupled to a set of devices 30 according to the present disclosure, for instance equipped with a set of power MOSFETs that have been tested according to a method as per the present disclosure.

As exemplified in FIG. 3, a device 30 comprises a circuit 10, 10′ as per the present disclosure, and an electrical supply source V_STRESS_MIN configured to provide a stress voltage. As illustrated in FIG. 4, the electronic device 30 may be equipped onboard an automotive vehicle V, e.g., an electrically powered automotive vehicle.

One or more embodiments may thus provide improved robustness against malfunctioning of the power MOSFETs exploited by ECUs 40, 50 on-board the vehicle. This may be advantageous to fulfill safety requirements in the automotive field.

For instance, an energy management system (EMS) unit 40 configured to manage energy of the vehicle V is coupled to the device 30 as per the present disclosure.

A method as exemplified herein comprises providing a set of electronic switches Q1, . . . , Qn having a current line therethrough between a supply node VDD and ground GND. Each electronic switch in the set of electronic switches comprises a respective control node G1, . . . , Gn to receive a calibrated stress test voltage V_STRESS_MIN.

One end of coupling channels of a set of coupling channels 101, . . . , 10n is coupled to a common test node TEST_PAD and the other ends of coupling channels of a set of coupling channels are coupled to respective control nodes of electronic switches in the set of electronic switches. The set of coupling channels is configured to propagate application of a test voltage V_STRESS_MIN from the common test node to respective control nodes of the electronic switches in the set of electronic switches. Based on an enable calibration signal TS having a first logic value, a first input node of comparator circuits of a set of comparator circuits 140; 141, . . . , 14n is coupled to the control node of respective electronic switches in the set of electronic switches.

A threshold voltage level V_REF is provided to a second input node of comparator circuits of the set of comparator circuits. The test voltage is applied to the common node TEST_PAD. A set of control voltages are sensed at the first input nodes of the set of comparators. The set of control voltages comprises control voltages sensed at the control nodes of the electronic switches in the set of electronic switches.

A set of comparisons 140; 141, . . . , 14n of the set of sensed control voltages and the threshold reference voltage is performed, producing a set of comparison signals VGS_COMP; VGS_COMP1, . . . , VGS_COMP2 having a first logic value in response to sensed control voltages in the set of sensed control voltages exceeding the threshold reference voltage and a second logic value in response to the sensed control voltages in the set of sensed control voltages failing to exceed the threshold reference voltage.

In response to at least one comparison signal VGS_COMP in the set of comparison signals VGS_COMP1, . . . , VGS_COMP2 having the second logic value, the test voltage applied at the common test node is increased. The set of comparisons is interrupted and the test voltage applied at the common test node is increased in response to each and every comparison signal in the set of comparison signals having the first logic value. The value reached by the test voltage applied at the common test node is provided as a calibrated stress test voltage value to a user circuit.

For instance, in response to the calibration enable signal having the first logic value, at least one resistive voltage divider R1, R2, R3 is coupled (e.g., by switch SW2) to control nodes of the electronic switches in the set of control switches, The sensed control voltages are sensed via the at least one resistive voltage divider as a result. A supply voltage level V3V3 is coupled at one end of a series arrangement of resistive elements referred to ground R4, R5, providing the threshold reference voltage at a node intermediate the series arrangement as a result. Resistive elements in the resistive voltage divider have resistance values based on resistance values of resistive elements in the series arrangement of resistive elements coupled to the supply voltage level.

As exemplified herein, the set of electronic switches is coupled to a set of driving circuits 120; 121, . . . , 12n. Control nodes of electronic switches in the set of electronic switches are coupled to an output node 1201; 1211, . . . , 121n of a respective driving circuit in the set of driving circuits. Each control node is configured to receive a control signal from a respective driving circuit. The current flow line is configured to be made at least partially conductive or non-conductive based on a logic value of said control signal.

As exemplified herein, electronic switches in the set of electronic switches comprise transistors, preferably, MOSFET transistors.

For instance, increasing the test voltage comprises step-wise increasing the test voltage starting from a minimum voltage level to a maximum voltage level, preferably by a step about 100 mV.

A test circuit 10, 10′, 30 as exemplified in any one of FIGS. 1 to 3 comprises a set of electronic switches Q1, . . . , Qn configured to have a current line therethrough between a first node VDD and ground GND. Each electronic switch in the set of electronic switches comprises a respective control node to receive a calibrated stress test voltage V_STRESS_MIN.

A set of coupling channels 101, . . . , 10n have one end coupled to a common test node TEST_PAD and other ends coupled to respective control nodes G1, . . . , Gn of electronic switches in the set of electronic switches. The set of coupling channels 101, . . . , 10n are configured to propagate application of a test voltage V_STRESS_MIN from the common test node to respective control nodes of the electronic switches in the set of electronic switches

A threshold voltage node is configured to receive a threshold voltage V_REF and a stress voltage supply source is configured to apply a calibrated stress test voltage to the common node. A set of comparator circuits 140; 141, . . . , 14n comprise comparator circuits having a first input node coupled, via sensing circuitry (e.g., R1, R2, R3), to the control node of respective electronic switches in the set of electronic switches. The comparator circuits have second nodes coupled to the threshold voltage node.

The sensing circuitry is configured to sense a set of control voltages at the control nodes of the electronic switches in the set of electronic switches. The set of comparator circuits is configured to perform a set of comparisons of the set of sensed control voltages and the threshold reference voltage and to produce a set of comparison signals having a first logic value in response to sensed control voltages in the set of sensed control voltages exceeding the threshold reference voltage and a second logic value in response to the sensed control voltages in the set of sensed control voltages failing to exceed the threshold reference voltage, the set of comparators configured to provide the set of comparison signals VGS_COMP; VGS_COMP1, . . . , VGS_COMP2 to a user circuit.

As exemplified in any one of FIGS. 1 to 3, the sensing circuitry comprises at least one resistive voltage divider R1, R2, R3 referred to ground coupled to control nodes of the electronic switches in the set of control switches, sensing the sensed control voltages via the at least one resistive voltage divider as a result. The threshold voltage node is coupled to a supply voltage level V3V3 at one end of a series arrangement of resistive elements referred to ground R4, R5, providing the threshold reference voltage V_REF at a node intermediate the series arrangement as a result. Resistive elements in the resistive voltage divider have resistance values based on resistance values of resistive elements in the series arrangement of resistive elements.

As exemplified in any one of FIGS. 1 to 3, the set of electronic switches is coupled to a set of driving circuits 120; 121, . . . , 12n, Control nodes of electronic switches in the set of electronic switches are coupled to an output node 1201; 1211, . . . , 121n of a respective driving circuit in the set of driving circuits. Each control node is configured to receive a control signal from a respective driving circuit. The current flow line is configured to be made conductive or non-conductive based on a logic value of said control signal.

As exemplified in any one of FIGS. 1 to 3, electronic switches in the set of electronic switches comprise transistors, preferably MOSFET transistors.

As exemplified in FIG. 4, a vehicle (e.g., a battery-powered wheeled vehicle) can be equipped with the test circuit 10, 10′, 30 according to any one of FIGS. 1 to 3.

It will be otherwise understood that the various individual implementing options exemplified throughout the figures accompanying this description are not necessarily intended to be adopted in the same combinations exemplified in the figures. One or more embodiments may thus adopt these (otherwise non-mandatory) options individually and/or in different combinations with respect to the combination exemplified in the accompanying figures.

Without prejudice to the underlying principles, the details and embodiments may vary, even significantly, with respect to what has been described by way of example only, without departing from the extent of protection. The extent of protection is defined by the annexed claims.

What is claimed is:

1. A method, comprising:
providing a set of electronic switches having a current path between a supply node and ground, wherein each electronic switch in the set of electronic switches comprises a respective control node to receive a stress test voltage;
coupling one end of coupling channels of a set of coupling channels to a common test node and other ends of the coupling channels of the set of coupling channels to respective control nodes of electronic switches in the set of electronic switches, wherein the set of coupling channels is configured to propagate application of a test voltage from the common test node to respective control nodes of the electronic switches in the set of electronic switches;
based on an enable calibration signal having a first logic value, coupling a first input node of comparator circuits of a set of comparator circuits to the control node of respective electronic switches in the set of electronic switches;
providing a threshold voltage level to a second input node of comparator circuits of the set of comparator circuits;
applying the test voltage to the common test node;
sensing at the first input nodes of the set of comparators a set of control voltages comprising control voltages sensed at the control nodes of the electronic switches in the set of electronic switches;
performing a set of comparisons of the set of sensed control voltages and the threshold voltage level thereby producing a set of comparison signals having the first logic value in response to sensed control voltages in the set of sensed control voltages exceeding the threshold voltage level and a second logic value in response to the sensed control voltages in the set of sensed control voltages failing to exceed the threshold voltage level;
in response to at least one comparison signal in the set of comparison signals having the second logic value, increasing the test voltage applied at the common test node;
interrupting performing the set of comparisons and increasing the test voltage applied at the common test node in response to each and every comparison signal in the set of comparison signals having the first logic value; and
providing a value reached by the test voltage applied at the common test node as a calibrated stress test voltage value to a user circuit.

2. The method of claim 1, comprising:
in response to the calibration enable signal having the first logic value, coupling at least one resistive voltage divider to control nodes of the electronic switches in the set of control switches to sense the sensed control voltages via the at least one resistive voltage divider as a result; and
coupling a supply voltage level at one end of a series arrangement of resistive elements referred to ground thereby providing the threshold voltage level at a node intermediate the series arrangement as a result, wherein resistive elements in the resistive voltage divider have resistance values based on resistance values of resistive elements in the series arrangement of resistive elements coupled to the supply voltage level.

3. The method of claim 1, wherein the set of electronic switches is coupled to a set of driving circuits and wherein control nodes of electronic switches in the set of electronic switches are coupled to an output node of a respective driving circuit in the set of driving circuits, each control node configured to receive a control signal from a respective driving circuit of the set of driving circuits, wherein the current path is configured to be made at least partially conductive or non-conductive based on a logic value of the control signal.

4. The method of claim 1, wherein electronic switches in the set of electronic switches comprise transistors.

5. The method of claim 1, wherein electronic switches in the set of electronic switches comprise MOSFET transistors.

6. The method of claim 1, wherein increasing the test voltage comprises step-wise increasing the test voltage starting from a minimum voltage level to a maximum voltage level.

7. The method of claim 1 wherein step-wise increasing the test voltage comprises increasing the test voltage in steps of about 100 mV.

8. A test circuit comprising:
a set of electronic switches having a current path between a first node and a ground node, wherein each electronic switch comprises a respective control node;
a set of coupling channels having one end coupled to a common test node and other ends coupled to the respective control nodes of electronic switches;
a stress voltage supply source coupled to the common test node;
a threshold voltage node;
sensing circuitry; and
a set of comparator circuits comprising comparator circuits having a first input node coupled, via the sensing circuitry, to the control node of respective electronic switches in the set of electronic switches and having second nodes coupled to the threshold voltage node.

9. The test circuit of claim 8, wherein each electronic switch comprises a respective control node to receive a calibrated stress test voltage and wherein the set of coupling channels are configured to propagate application of a test voltage from the common test node to respective control nodes of the electronic switches in the set of electronic switches.

10. The test circuit of claim 8, wherein the sensing circuitry comprises at least one resistive voltage divider referred to ground coupled to control nodes of the electronic switches in the set of control switches; and
wherein the threshold voltage node is coupled to a supply voltage level at one end of a series arrangement of resistive elements referred to ground.

11. The test circuit of claim 10, wherein resistive elements in the resistive voltage divider have resistance values based on resistance values of resistive elements in the series arrangement of resistive elements.

12. The test circuit of claim 8, wherein the set of electronic switches is coupled to a set of driving circuits and wherein control nodes of electronic switches in the set of electronic switches are coupled to an output node of a respective driving circuit in the set of driving circuits, each control node configured to receive a control signal from a respective driving circuit.

13. The test circuit of claim 8, wherein the electronic switches in the set of electronic switches comprise MOSFET transistors.

14. A method of operating the test circuit of claim 8, the method comprising:
providing a threshold voltage level to a second input node of comparator circuits of the set of comparator circuits;
applying a test voltage to the test common node;
sensing a set of control voltages at the first input nodes of the set of comparators;
performing a set of comparisons of the set of sensed control voltages and a threshold voltage level thereby producing a set of comparison signals having a first logic value in response to sensed control voltages in the set of sensed control voltages exceeding the threshold voltage level and a second logic value in response to the sensed control voltages in the set of sensed control voltages failing to exceed the threshold voltage level;
in response to at least one comparison signal in the set of comparison signals having the second logic value, increasing the test voltage applied at the test common node; and
increasing the test voltage applied at the common test node in response to each and every comparison signal in the set of comparison signals having the first logic value, wherein a value reached by the test voltage applied at the common test node is determined as a calibrated stress test voltage value.

15. A test circuit, comprising:
a set of electronic switches configured to have a current path therethrough between a first node and ground, wherein each electronic switch in the set of electronic switches comprises a respective control node to receive a calibrated stress test voltage;
a set of coupling channels having one end coupled to a common test node and other ends coupled to respective control nodes of electronic switches in the set of electronic switches, wherein the set of coupling channels are configured to propagate application of a test voltage from the common test node to respective control nodes of the electronic switches in the set of electronic switches;
a threshold voltage node configured to receive a threshold voltage;
a stress voltage supply source configured to apply a calibrated stress test voltage to the common test node;
sensing circuitry; and
a set of comparator circuits comprising comparator circuits having a first input node coupled, via the sensing circuitry, to the control node of respective electronic switches in the set of electronic switches and having second nodes coupled to the threshold voltage node;
wherein the sensing circuitry is configured to sense a set of control voltages at the control nodes of the electronic switches in the set of electronic switches; and
wherein the set of comparator circuits is configured to perform a set of comparisons of the set of sensed control voltages and the threshold voltage and to produce a set of comparison signals having a first logic value in response to sensed control voltages in the set of sensed control voltages exceeding the threshold voltage and a second logic value in response to the sensed control voltages in the set of sensed control voltages failing to exceed a reference voltage.

16. The test circuit of claim 15, wherein the set of comparators is configured to provide the set of comparison signals to a user circuit.

17. The test circuit of claim 15, wherein the set of electronic switches is coupled to a set of driving circuits, wherein control nodes of electronic switches in the set of electronic switches are coupled to an output node of a respective driving circuit in the set of driving circuits, each control node configured to receive a control signal from a respective driving circuit, and wherein the current path is configured to be made conductive or non-conductive based on a logic value of said control signal.

18. The test circuit of claim 15, wherein electronic switches in the set of electronic switches comprise transistors.

19. The test circuit of claim 18, wherein electronic switches in the set of electronic switches comprise MOSFET transistors.

20. A vehicle equipped with the test circuit according to claim 15, wherein the vehicle comprises a battery-powered wheeled vehicle.
